(19) United States
(12) Patent Application Publication
(10) Pub. No.: US 2022/0173020 A1
(43) Pub. Date: Jun. 2, 2022

(54) AN ELECTRICAL CONNECTION STRUCTURE AND AN ELECTRONIC DEVICE INCLUDING THE SAME

(71) Applicant: Infineon Technologies AG, Neubiberg (DE)

(72) Inventors: Wee Boon Tay, Melaka (MY); Wei Hing Tan, Muenchen (DE); Hooi Boon Teoh, Melaka (MY)

(21) Appl. No.: 17/539,255

(22) Filed: Dec. 1, 2021

(30) Foreign Application Priority Data
Dec. 1, 2020 (DE) 102020131810.3

(51) Int. Cl. H01L 23/495; H01L 23/00

(52) U.S. Cl. CPC H01L 23/49541; H01L 2224/48175; H01L 24/48

(57) ABSTRACT

An electrical connection structure includes a first metallic lead having a first contact area, a second metallic lead having a second contact area, and a connection region connecting the first and second leads with each other. The connection region includes a trench. The trench includes a planar rectangular horizontal floor surface and vertical walls adjacent to the planar rectangular floor surface.

### TECHNICAL FIELD

The present disclosure is related to an electrical connection structure and an electronic device comprising an electrical connection structure.

### BACKGROUND

Electronic devices like semiconductor packages need an electrical connection structure between the electronic device and outer electrical components. The electrical connection structure usually comprises electrical connectors like wire bonds or clips and metallic leads wherein inner ends of the connectors are connected with contact pads of the electronic device and outer ends of the connectors are connected with the metallic leads. Very often the connections between outer ends of the connectors and the leads are accomplished by soldering, in particular when clips are used as the connectors.

Furthermore there exist electrical connection structures in which two of the metallic leads are connected with each other and at least a first one of them is connected with a clip by soldering. In such a situation it may occur that during soldering excessive solder material flows out of the contact area of the first lead in the direction of a second lead. Such a solder flux overflow may lead to severe problem, in particular if the second lead is to be connected with a wire bond it may lead to high occurrences of non-stick on lead (NSOL) reject so that the bond wire cannot be connected with the second lead.

For these and other reasons there is a need for the presence disclosure.

### SUMMARY

A first aspect of the present disclosure is related to an electrical connection structure, comprising a first metallic lead comprising a first contact area, a second metallic lead comprising a second contact area, a connection region connecting the first and second leads with each other, the connection region comprising a trench, wherein the trench comprises a planar rectangular horizontal floor surface and vertical walls adjacent to the floor surface.

A second aspect of the present disclosure is related to an electronic device, comprising one or more electronic components comprising contact pads, an electrical connection structure comprising a first metallic lead comprising a first contact area, a second metallic lead comprising a second contact area, a connection region connecting the first and second leads with each other, the connection region comprising a trench, wherein the trench comprises a planar rectangular horizontal floor surface and vertical walls adjacent to the floor surface, and electrical connectors connected between the contact pads and the electrical connection structure.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description.

The elements of the drawings are not necessarily to scale relative to each other. Like reference numerals designate corresponding similar parts.

FIGS. 1A to 1C show an example of an electrical connection structure in a perspective view from above whilst also showing portions of the metallic leads outside the connection structure (FIG. 1A), in a perspective view from a direction different to FIG. 1A (FIG. 1B) whilst only showing portions of the metallic leads being part of the connection structure, and in a perspective view from a direction different to FIG. 1A and FIG. 1B whilst only showing portions of the metallic leads being part of the connection structure (FIG. 1C).

FIG. 2 shows an example of an electrical connection structure together with the connectors to the electronic device in a top view from above.

FIG. 3 shows an example of an electronic device together with an electrical connection structure as of one of FIGS. 1A-1C or FIG. 2 in a top view from above.

### DETAILED DESCRIPTION

In the following detailed description, reference is made to the accompanying drawings, which form a part hereof, and in which is shown by way of illustration specific embodiments in which the disclosure may be practiced. In this regard, directional terminology, such as “top”, “bottom”, “front”, “back”, “leading”, “trailing”, etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present disclosure. The following detailed description, therefore, is not to be taken in a limiting sense, and the scope of the present disclosure is defined by the appended claims.

It is to be understood that the features of the various exemplary embodiments described herein may be combined with each other, unless specifically noted otherwise.

As employed in this specification, the terms “bonded”, “attached”, “connected”, “coupled” and/or “electrically connected/electrically coupled” are not meant to mean that the elements or layers must directly be contacted together; intervening elements or layers may be provided between the “bonded”, “attached”, “connected”, “coupled” and/or “electrically connected/electrically coupled” elements, respectively. However, in accordance with the disclosure, the above-mentioned terms may, optionally, also have the specific meaning that the elements or layers are directly contacted together, i.e. that no intervening elements or layers are provided between the “bonded”, “attached”, “connected”, “coupled” and/or “electrically connected/electrically coupled” elements, respectively.

Further, the word “over” used with regard to a part, element or material layer formed or located “over” a surface may be used herein to mean that the part, element or material layer be located (e.g. placed, formed, deposited, etc.) “indirectly on” the implied surface with one or more additional parts, elements or layers being arranged between the implied surface and the part, element or material layer. However, the word “over” used with regard to a part, element or material layer formed or located “over” a surface may, optionally, also have the specific meaning that the part, element or material layer be located (e.g. placed, formed, deposited, etc.) “directly on”, e.g. in direct contact with, the implied surface.

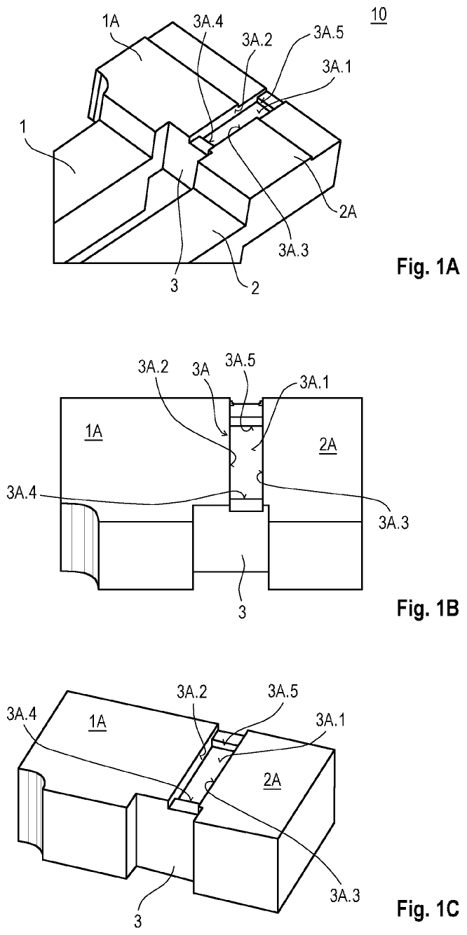

FIGS. 1A to 1C show an example of an electrical connection structure.

The electrical connection structure 10 as shown in FIG. 1A comprises a first metallic lead comprising a first contact area 1A, a second metallic lead 2 comprising a second contact area 2A, a connection region 3 connecting the first and second leads 1 and 2 with each other, the connection region 3 comprising a trench 3A, wherein the trench 3A comprises a planar rectangular horizontal floor surface 3A.1 and vertical walls 3A.2 to 3A.5 adjacent to the floor surface 3A.1.

Also shown in FIG. 1A are portions of the metallic leads 1 and 2 outside the connection structure 10 and extending parallel to each other in a direction away from the electrical connection structure 10.

It can be the case that the first lead 1 is to be connected with one end of a clip the other end of which is to be connected with a contact pad of a first electronic device like a semiconductor die. It can furthermore be provided that the second lead is to be connected with one end of a bond wire the other end of which is to be connected with a contact pad of a second electronic device which can also be a semiconductor die.

In any case, the first lead 1 is to be connected by with one end of a first connector by a soldering process and excess solder material should be prevented from flowing during the soldering process from the first contact area 1 over a side edge of the first contact area 1A of the first lead 1 to the second contact area 2A of the second lead 2. The trench 3A formed into the connection region 3 effectively serves this purpose in that it functions as an efficient reservoir for the flowing solder material. The improved design of the trench 3A with closed ends ensures that the solder material does not flow to the side wall of the leads. Excessive fluent solder material will only flow into and fill up the trench 3A and thus be prevented to reach the second contact area 2A of the second lead 2 and thereby contaminate the second contact area 2A.

As can also be seen in the example of FIGS. 1A to 1C, the trench 3A is enclosed on all sides. This ensures that the solder material is collected in the trench 3A and cannot escape from the trench 3A.

As can also be seen in the example of FIGS. 1A to 1C, the first and second contact areas 1A and 2A may both comprise planar surfaces being disposed in one and the same plane and the walls 3A.2 to 3A.5 of the trench 3A are perpendicular to the surfaces of the first and second contact areas 1A and 2A.

Furthermore according to the example of FIGS. 1A to 1C, the walls 3A.2 to 3A.5 of the trench 3A may comprise a front wall 3A.2 on the side of the first metallic lead 1, a back wall 3A.3 on the side of the second metallic lead 2, and side walls 3A.4 and 3A.5 connecting the front and back walls 3A.2 and 3A.5 with each other. Furthermore as can also be seen in FIGS. 1A to 1C, it can be provided that the height of the side walls 3A.4 and 3A.5 is lower than the height of the front and back walls 3A.2 and 3A.3. In other words, an upper edge of the side walls 3A.4 and 3A.5 lies in a plane which is below the plane of the first and second contact areas 1A and 2A.

As is also shown in the example of FIGS. 1A to 1C, the trench 3A may furthermore comprise an elongate shape wherein in a longitudinal direction the trench 3A extends along opposing side edges of the first and second contact areas 1A and 2A.

According to another example of the electrical connection structure 10, the trench 3A comprises an elongate shape and comprises a length to width ratio with a value of 2 or more, or a value in a range from 2 to 10.

According to another example of the electrical connection structure 10, the trench 3A comprises a spatial volume with a value 0.001 mm³ or more, or a value in a range from 0.001 mm³ to 0.01 mm³.

According to another example of the electrical connection structure 10, the trench 3A the trench 3A comprises a length with a value of 0.3 mm or more, or a value in a range from 0.3 mm to 0.9 mm.

According to another example of the electrical connection structure 10, the trench 3A comprises a width with a value of 0.1 mm or more, or a value in a range from 0.1 mm to 0.3 mm.

According to another example of the electrical connection structure 10, the trench 3A comprises a depth with a value of 0.03 mm or more, or a value in a range from 0.03 mm to 0.07 mm.

According to further example of the electrical connection structure 10, there can be provided a spatial distance between the first contact area 1A and the trench 3A. According to a further example thereof, the spatial distance is 300 μm or less, or in a range between 50 μm and 300 μm.

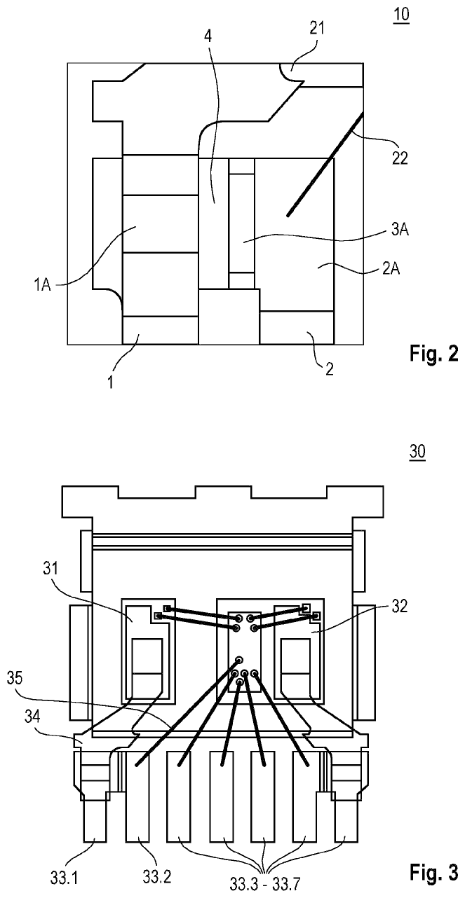

FIG. 2 shows an example of an electrical connection structure.

More specifically, FIG. 2 shows the electrical connection structure 10 in a top view from above wherein the electrical connection structure can be basically the same or can comprise basically the same properties and features as those which were described in connection with the electrical connection structure 10 of FIGS. 1A to 1C.

Moreover in FIG. 2 the electrical connection structure 10 is shown together with the connectors to the electronic device. Only lower portions of the connectors are shown whereas upper portions are not shown which are connected with an electronic device. The connectors are comprised of a clip 21 and a bond wire 22. The clip 21 is connected via a solder layer with the first contact area 1A of the first lead, whereas the bond wire 22 is connected with the second contact area 2A of the second lead 2.

The example of an electrical connection structure as shown in FIG. 2 also discloses a spatial distance 4 between the first contact area 1A and the trench 3A. The spatial distance is, however, only optional and no compelling feature.

FIG. 3 shows an example of an electronic device together with an electrical connection structure.

More specifically, FIG. 3 shows a schematic top view on an example of an electronic device 30 which comprises a first electronic component 31 and a second electronic component 32. Both first and second electronic components 31 and 32 can be semiconductor dies like, for example, MOSFET dies or IC dies.

The electronic device 30 is connected with a plurality of leads 33.1 to 33.7, wherein the leads 33.1 and 33.2 correspond to the leads 1 and 2 as shown in FIGS. 1 and 2. The leads 33.1 and 33.2 are electrically connected with each other at their respective upper portions and form an electrical connection structure there as was described above. A clip 34 is connected with its one end with a first contact area of the first lead 33.1 by a solder layer whereas another end of the clip 34 is connected with contact pad of the first electronic component 31. A bond wire 35 is connected with its one end with a second contact area of the second lead 33.1 whereas another end of the bond wire 35 is connected with contact pad of the second electronic component 32.

In the following, electrical connection structures and electronic devices will be explained by means of examples.

Example 1 is an electrical connection structure, comprising a first metallic lead comprising a first contact area, a second metallic lead comprising a second contact area, a connection region connecting the first and second leads with each other, the connection region comprising a trench, wherein the trench comprises a planar rectangular horizontal floor surface and vertical walls adjacent to the floor surface.

Example 2 is the electrical connection structure according to Example 1, wherein the trench is enclosed on all sides.

Example 3 is the electrical connection structure according to Example 1 or 2, wherein the first and second contact areas both comprise planar surfaces being disposed in one and the same plane, wherein the walls of the trench are perpendicular to the surfaces of the first and second contact areas.

Example 4 is the electrical connection structure according to any one of the preceding Examples, wherein the walls of the trench comprise a front wall on the side of the first metallic lead, a back wall on the side of the second metallic lead, and side walls connecting the front and back walls with each other.

Example 5 is the electrical connection structure according to Example 4, wherein the height of the side walls is lower than the height of the front and back walls.

Example 6 is the electrical connection structure according to any one of the preceding Examples, wherein the trench comprises an elongate shape wherein in a longitudinal direction the trench extends along opposing side edges of the first and second contact areas.

Example 7 is the electrical connection structure according to any one of the preceding Examples, wherein the trench comprises a length to width ratio of 2 or more, or in a range from 2 to 10.

Example 8 is the electrical connection structure according to any one of the preceding Examples, wherein the trench comprises a spatial volume of at least 0.001 mm³, or in a range from 0.001 mm³ to 0.01 mm³.

Example 9 is an electronic device, comprising one or more electronic components comprising contact pads, an electrical connection structure comprising a first metallic lead comprising a first contact area, a second metallic lead comprising a second contact area, a connection region connecting the first and second leads with each other, the connection region comprising a trench, wherein the trench comprises a planar rectangular horizontal floor surface and vertical walls adjacent to the floor surface, and electrical connectors connected between the contact pads and the electrical connection structure.

Example 10 is the electronic device according to Example 9, wherein the first and second contact areas both comprise planar surfaces being disposed in one and the same plane, wherein the walls of the trench are perpendicular to the surfaces of the first and second contact areas.

Example 11 is the electronic device according to Example 9 or 10, wherein the walls of the trench comprise a front wall adjacent to the first metallic lead, back wall adjacent to the second metallic lead, and side walls connecting the front and back walls with each other.

Example 12 is the electronic device according to Example 11, wherein the height of the side walls is smaller than the height of the front and back walls.

Example 13 is the electronic device according to any one of Examples 9 to 12, wherein the trench comprises an elongate shape wherein in a longitudinal direction the trench extends along opposing side edges of the first and second contact areas.

Example 14 is the electronic device according to any one of Examples 9 to 13, wherein the trench comprises a length to width ratio of 2 or more, or in a range from 2 to 10.

Example 15 is the electronic device according to any one of Examples 9 to 14, wherein the trench comprises a spatial volume in a range from 0.001 mm³ to 0.01 mm³.

Example 16 is the electronic device according to any one of Examples 9 to 15, wherein the trench comprises a length in a range from 0.3 mm to 0.9 mm.

Example 17 is the electronic device according to any one of Examples 9 to 16, wherein a first electrical connector is connected between a contact pad of a first electrical component and the first contact area, and a second electrical connector is connected between a contact pad of a second electrical component and the second contact area.

Example 18 is the electronic device according to any one of Examples 9 to 17, further comprising a first electrical connector in the form of a clip connected between one of the contact pads and the first contact area of the electrical connection structure.

Example 19 is the electronic device according to any one of Examples 9 to 18, further comprising a solder layer disposed between the clip and the first contact area.

Example 20 is the electronic device according to any one of examples 9 to 19, further comprising a second electrical connector in the form of a bond wire connected between one of the contact pads and the second contact area of the electrical connection structure

In addition, while a particular feature or aspect of an embodiment of the disclosure may have been disclosed with respect to only one of several implementations, such feature or aspect may be combined with one or more other features or aspects of the other implementations as may be desired and advantageous for any given or particular application. Furthermore, to the extent that the terms “include”, “have”, “with”, or other variants thereof are used in either the detailed description or the claims, such terms are intended to be inclusive in a manner similar to the term “comprise”. Furthermore, it should be understood that embodiments of the disclosure may be implemented in discrete circuits, partially integrated circuits or fully integrated circuits or programming means. Also, the term “exemplary” is merely meant as an example, rather than the best or optimal. It is also to be appreciated that features and/or elements depicted herein are illustrated with particular dimensions relative to one another for purposes of simplicity and ease of understanding, and that actual dimensions may differ substantially from that illustrated herein.

Although specific embodiments have been illustrated and described herein, it will be appreciated by those of ordinary skill in the art that a variety of alternate and/or equivalent implementations may be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof.

What is claimed is:

1. An electrical connection structure, comprising:
a first metallic lead comprising a first contact area;
a second metallic lead comprising a second contact area; and
a connection region connecting the first and second metallic leads with each other, the connection region comprising a trench,
wherein the trench comprises a planar rectangular horizontal floor surface and vertical walls adjacent to the planar rectangular horizontal floor surface.

2. The electrical connection structure of claim 1, wherein the trench is enclosed on all sides.

3. The electrical connection structure of claim 1, wherein the first and second contact areas both comprise planar surfaces disposed in one and the same plane, and wherein the vertical walls of the trench are perpendicular to the planar surfaces of the first and second contact areas.

4. The electrical connection structure of claim 1, wherein the vertical walls of the trench comprise a front wall on a side of the first metallic lead, a back wall on a side of the second metallic lead, and side walls connecting the front and back walls with each other.

5. The electrical connection structure of claim 4, wherein a height of the side walls is lower than a height of the front and back walls.

6. The electrical connection structure of claim 1, wherein the trench has an elongate shape, and wherein in a longitudinal direction, the trench extends along opposing side edges of the first and second contact areas.

7. The electrical connection structure of claim 1, wherein the trench has a length to width ratio of 2 or more, or in a range from 2 to 10.

8. The electrical connection structure of claim 1, wherein the trench has a spatial volume of at least 0.001 mm³, or in a range from 0.001 mm³ to 0.01 mm³.

9. An electronic device, comprising:
one or more electronic components comprising contact pads;
an electrical connection structure comprising
a first metallic lead comprising a first contact area;
a second metallic lead comprising a second contact area;
a connection region connecting the first and second leads with each other, the connection region comprising a trench, the trench comprising a planar rectangular horizontal floor surface and vertical walls adjacent to the planar rectangular floor surface; and
electrical connectors connected between the contact pads and the electrical connection structure.

10. The electronic device of claim 9, wherein the first and second contact areas both comprise planar surfaces disposed in one and the same plane, and wherein the vertical walls of the trench are perpendicular to the planar surfaces of the first and second contact areas.

11. The electronic device of claim 9, wherein the vertical walls of the trench comprise a front wall adjacent to the first metallic lead, a back wall adjacent to the second metallic lead, and side walls connecting the front and back walls with each other.

12. The electronic device of claim 11, wherein a height of the side walls is smaller than a height of the front and back walls.

13. The electronic device of claim 9, wherein the trench has an elongate shape, and wherein in a longitudinal direction, the trench extends along opposing side edges of the first and second contact areas.

14. The electronic device of claim 9, wherein the trench has a length to width ratio of 2 or more, or in a range from 2 to 10.

15. The electronic device of claim 9, wherein the trench has a spatial volume in a range from 0.001 mm³ to 0.01 mm³.

16. The electronic device of claim 9, wherein the trench has a length in a range from 0.3 mm to 0.9 mm.

17. The electronic device of claim 9, further comprising:
a first electrical connector connected between a contact pad of a first electrical component and the first contact area; and
a second electrical connector connected between a contact pad of a second electrical component and the second contact area.

18. The electronic device of claim 9, further comprising:
a clip connected between one of the contact pads and the first contact area of the electrical connection structure.

19. The electronic device of claim 18, further comprising:
a solder layer disposed between the clip and the first contact area.

20. The electronic device of claim 9, further comprising:
a bond wire connected between one of the contact pads and the second contact area of the electrical connection structure.
